(19) United States
(12) Patent Application Publication
(10) Pub. No.: US 2012/0161263 A1
(43) Pub. Date: Jun. 28, 2012

(54) Current perpendicular to plane (CPP) magnetoresistive sensor having dual composition hard bias layer

(76) Inventors: Stefan Maat, San Jose, CA (US); Alexander M. Zeltser, San Jose, CA (US)

(21) Appl. No.: 12/930,131

(22) Filed: Dec. 28, 2010

(51) Int. Cl. H01L 43/10

(52) U.S. Cl. 257/422; 257/E43.005

(57) ABSTRACT

A current-perpendicular-to-the-plane (CPP) magnetoresistive (MR) sensor has a dual composition hard bias layer structure that is used to longitudinally bias the sensor's free ferromagnetic layer. The dual composition hard bias layer structure is composed of first layer of CoPt, having high anisotropy compared to the second layer. The second layer, composed of CoFe, has a higher magnetization compared to the first layer. The resulting dual hard bias layer structure exhibits high values of coercivity and squareness while maintaining a reduced sensor thickness compared to sensors of the prior art.

### BACKGROUND OF THE INVENTION

1. Field of the Invention

This invention relates to structures in a current-perpendicular-to-the-plane (CPP) magnetoresistive (MR) sensor in a thin film magnetic head. More specifically, the invention relates to hard bias layer compositions having a first layer of high anisotropy compared to a second layer, the second layer having a high magnetization compared to the first layer.

2. Description of the Related Art

One type of conventional magnetoresistive (MR) sensor used as the read head in magnetic recording disk drives is a “spin valve” sensor based on the giant magnetoresistance (GMR) effect. A GMR spin-valve sensor has a stack of layers that includes two ferromagnetic layers separated by a nonmagnetic electrically conductive spacer layer, which is typically copper (Cu). One ferromagnetic layer adjacent the spacer layer has its magnetization direction fixed, such as by being pinned by exchange coupling with an adjacent antiferromagnetic layer, and is referred to as the reference layer. The other ferromagnetic layer adjacent the spacer layer has its magnetization direction free to rotate in the presence of an external magnetic field and is referred to as the free layer. With a sense current applied to the sensor, the rotation of the free-layer magnetization relative to the reference layer magnetization due to the presence of an external magnetic field is detectable as a change in electrical resistance. If the sense current is directed perpendicularly through the planes of the layers in the sensor stack, the sensor is referred to as a current-perpendicular-to-the-plane (CPP) sensor.

Another type of CPP MR sensor is a magnetic tunnel junction sensor, also called a “tunneling MR” or TMR sensor, in which the nonmagnetic conductive spacer layer of the GMR sensor is replaced by a very thin nonmagnetic tunnel barrier layer made from a generally insulating material such as TiO₂, MgO or Al₂O₃. In a CPP-TMR sensor the tunneling current flowing perpendicularly through the layers depends on the relative orientation of the magnetizations in the two ferromagnetic layers.

The sensor stack in a CPP MR read head is located between two shields of magnetically permeable material that shield the read head from recorded data bits on the disk that are neighboring the data bit being read. Layers within the sensor stack are approximately parallel with the two shield layers above and below the sensor stack. The sensor stack has an edge that faces the disk being approximately co-planar with the air bearing surface (ABS). Side edges determine the nominal width of the sensor stack layers. The nominal width of the sensor stack layers at the ABS determine the track width (TW) of the data being read by the sensor. The sensor stack is terminated by a back edge recessed from the edge that faces the disk, with the dimension from the ABS to the back edge referred to as the stripe height (SH). The sensor stack is generally surrounded at the side and back edges by insulating material. This is required to insure that the sense current flows perpendicular to the layers in the sensor stack. In some designs sense current flows through the sensor stack via the upper and lower shield layers. Alternatively, separate current leads can be provided for this purpose, a bottom lead in electrical contact with the bottom of the sensor and above the bottom shield, a top lead in electrical contact with the top of the sensor and below the bottom shield.

A layer of hard or high-coercivity ferromagnetic material is used as a “hard bias” layer to stabilize the magnetization of the free layer (within the sensor stack) longitudinally via magneto-static coupling. The hard bias layer is deposited over the insulating material on each side of the of the sensor stack, between the upper and lower shield layers. Seed layers are utilized between the insulating layer and the hard bias layer to aid in producing the desired magnetic properties of the hard bias layer. These seed layers may comprise one or more layers of different compositions, and are generally made as thin as possible. The hard bias layer is required to exhibit a generally in-plane magnetization direction with high coercivity (H_{c}) to provide a stable longitudinal bias field that maintains a single domain state in the free layer so that the free layer will be stable against all reasonable perturbations while the sensor maintains relatively high signal sensitivity. The hard bias layer must have sufficient in-plane remnant magnetization (Mᵣ), which may also be expressed as Mᵣ*t since Mᵣ by itself is independent of the thickness (t) of the hard bias layer. Mᵣ*t is the component that provides the longitudinal bias flux to the free layer and must be high enough to assure a single magnetic domain in the free layer but not so high as to prevent the magnetic field in the free layer from rotating under the influence of the magnetic fields from the recorded data bits. Furthermore, the hard bias layer should exhibit a high squareness (S) value approaching 1.0, where S=Mᵣ/Mₛ and Mₛ is the saturation magnetization.

The increase in data bit densities is requiring further shrinkage of magnetic head dimensions, decreasing the spacing between the upper and lower shield layers. The reduction of total sensor stack thickness also imposes the same reduction in hard bias layer thickness and the thickness of the seed layers. Whereas conventional designs of the prior art utilize a hard bias layer of a single composition, these designs may not provide the required magnetic properties if the hard bias+seed layer thickness is reduced further. One structure that appears useful for providing lower stack thickness employs a hard bias layer having a dual composition. The dual composition comprises a first layer of high anisotropy compared to the second layer, the second layer having a high magnetization compared to the first layer.

What is needed is a CPP MR sensor with an improved hard bias layer structure that can be made thinner yet still provide desirable magnetic properties for the hard bias layer.

### SUMMARY OF THE INVENTION

It is an object of the present invention to provide a thin film magnetic head having a current perpendicular to plane magnetoresistive sensor including a first shield layer; a sensor stack of layers deposited on an upper surface of the first shield layer, the sensor stack having a width at the air bearing surface defined by first and second side edges; an insulating layer deposited on the first and second side edges of the sensor stack, and a portion of the upper surface of the first shield layer; a first seed layer deposited on the insulating layer, the first seed layer comprising Ta; a second seed layer deposited on the first seed layer, the second seed layer comprising W; a first hard bias layer deposited on the second seed layer, the first hard bias layer comprising alloys of Co and Pt; a second hard bias layer deposited on the first hard bias layer, the second hard bias layer comprising alloys of Co and Fe; a capping layer deposited on the second hard bias layer; and a second shield layer deposited on the capping layer, the sensor stack disposed between the first and second shield layers.

It is another object of the present invention to provide a thin film magnetic head having a current perpendicular to plane magnetoresistive sensor including a first shield layer; a sensor stack of layers deposited on an upper surface of the first shield layer, the sensor stack having a width at the air bearing surface defined by first and second side edges; an insulating layer deposited on the first and second side edges of the sensor stack, and a portion of the upper surface of the first shield layer; a first seed layer deposited on the insulating layer, the first seed layer comprising Ta; a second seed layer deposited on the first seed layer, the second seed layer comprising W; a first hard bias layer deposited on the second seed layer, the first hard bias layer comprising alloys of Co and Pt; a second hard bias layer deposited on the first hard bias layer, the second hard bias layer comprising alloys of Co and Fe, the first and second hard bias layers having a combined thickness less than 150 angstroms and a coercivity H_{c} greater than 2000 Oe; a capping layer deposited on the second hard bias layer; and a second shield layer deposited on the capping layer, the sensor stack disposed between the first and second shield layers.

### BRIEF DESCRIPTION OF THE DRAWINGS

The present invention will be better understood when consideration is given to the following detailed description thereof. Such description makes reference to the annexed drawings, wherein:

FIG. 1 is a first partial cross section view of a CPP-MR sensor, in accordance with an embodiment of the present invention;

FIG. 2 is a second partial cross section view of a CPP-MR sensor, in accordance with an embodiment of the present invention;

FIG. 3 is a graph of total magnetic moment mₛ of a hard-bias structure having a CoPt₁₈/CoFe₅₀ bilayer, where the CoFe₅₀ layer thickness is varied in accordance with an embodiment of the present invention;

FIG. 4 is a graph of saturation magnetization Ms of a hard-bias structure having a CoPt₁₈/CoFe₅₀ bilayer, where the CoFe₅₀ layer thickness is varied in accordance with an embodiment of the present invention;

FIG. 5 is a graph of squareness S of a hard-bias structure having a CoPt₁₈/CoFe₅₀ bilayer, where the CoFe₅₀ layer thickness is varied in accordance with an embodiment of the present invention;

FIG. 6 is a graph of Mᵣ*t of a hard-bias structure having a CoPt₁₈/CoFe₅₀ bilayer, where the CoFe₅₀ layer thickness is varied in accordance with an embodiment of the present invention; and

FIG. 7 is a graph of coercivity H_{c} of a hard-bias structure having a CoPt₁₈/CoFe₅₀ bilayer, where the CoFe₅₀ layer thickness is varied in accordance with an embodiment of the present invention.

### DETAILED DESCRIPTION OF THE PREFERRED EMBODIMENTS

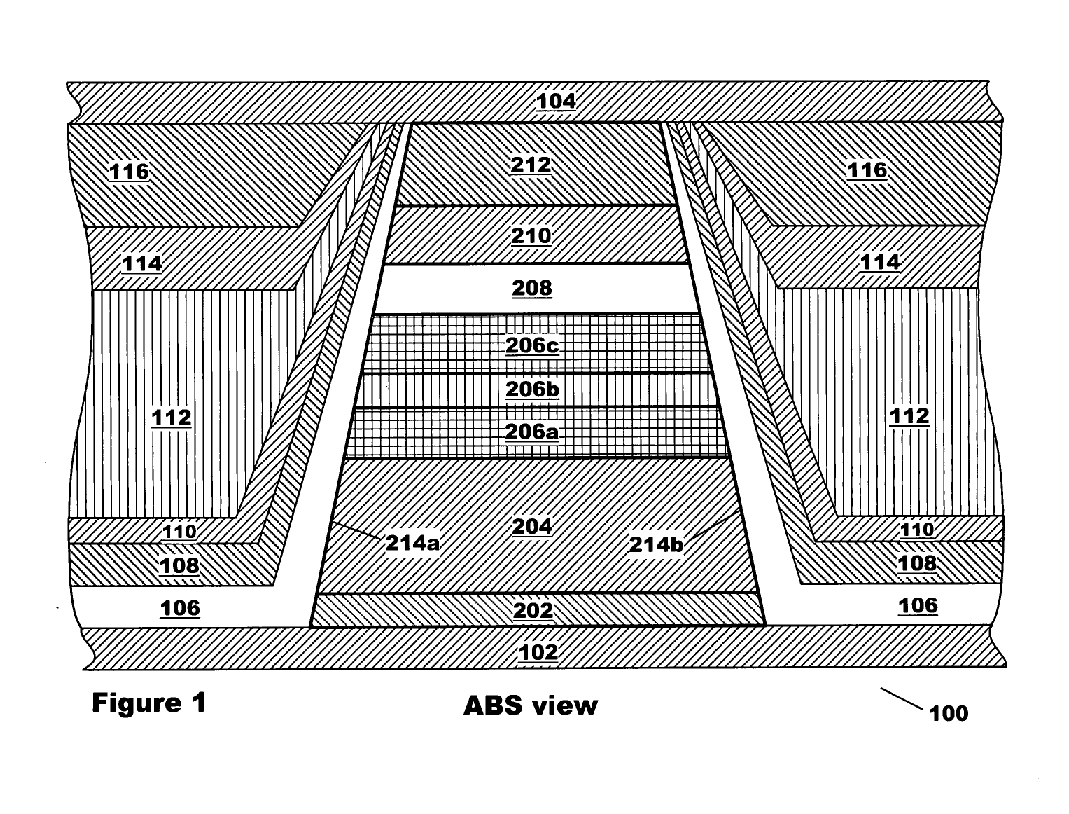

FIG. 1 is a partial cross section ABS view 100 of a CPP-MR sensor, in accordance with an embodiment of the present invention. Centrally located in FIG. 1 is the sensor stack, comprising layers 202 to 212. The sensor stack is situated between the upper shield layer 104 and the lower shield layer 102. A hard bias layer structure comprising layers 106-116 is deposited between sensor stack side edges 214a and 214b, the upper surface of lower shield layer 102, and the lower surface of upper shield layer 104. Insulating layer 106 is deposited on sensor stack side edges 214a and 214b and the upper surface of lower shield layer 102. Seed layers 108 and 110 are deposited over insulating layer 106, followed by hard bias layers 112 and 114. Capping layer 116 completes the hard bias layer structure, and is situated between hard bias layer 114 and upper shield layer 104. In this particular embodiment, sense current for the CPP-MR sensor is conducted through sensor stack layers 202-212 via the shield layers 104 and 102, which serve as top and bottom leads, respectively. However, as will be recognized by those skilled in the art, other conduction layers (not shown in FIG. 1) could be provided above and below the sensor stack for the same purpose.

The CPP-MR sensor stack layers include a reference ferromagnetic layer 206c having a fixed magnetic moment or magnetization direction, a “free” ferromagnetic layer 210 (the “free layer”) having a magnetic moment or magnetization direction that can rotate in the plane of layer 210 in response to transverse external magnetic fields from the disk media being read by the sensor stack, and a nonmagnetic spacer layer 208 between the reference layer 206c and free layer 210. The CPP MR sensor may be a CPP GMR sensor, in which case the nonmagnetic spacer layer 208 would be formed of an electrically conducting material, typically a metal like Cu, Au or Ag. Alternatively, the CPP MR sensor may be a CPP tunneling MR (CPP-TMR) sensor, in which case the nonmagnetic spacer layer 208 would be a tunnel barrier formed of an electrically insulating material, like TiO₂, MgO or Al₂O₃.

The pinned ferromagnetic layer structure (layers 206a, 206b, 206c) in the CPP MR sensor shown in FIG. 1 is generally referred to as an antiparallel (AP) pinned structure. Alternatively, a single pinned layer may also be used (not shown) as would be recognized by those skilled in the art. An AP-pinned structure has first (206a) and second (206c) ferromagnetic layers separated by a nonmagnetic antiparallel coupling layer 206b with the magnetization directions of the two AP-pinned ferromagnetic layers oriented substantially antiparallel. Here and in the following substantially antiparallel means closer to antiparallel than parallel. Layer 206c, which is in contact with the nonmagnetic coupling layer 206b on one side and the sensor's nonmagnetic spacer layer 208 on the other side, is typically referred to as the reference layer. Layer 206a, which is typically in contact with an antiferromagnetic or hard magnet pinning layer 204 on one side and the nonmagnetic coupling layer 206b on the other side (shown), is typically referred to as the pinned layer. Alternatively, instead of being in contact with a hard magnetic layer, the pinned layer 206a by itself can be comprised of hard magnetic material so that pinned layer 206a is in contact with an underlayer on one side and the nonmagnetic coupling layer 206b on the other side (not shown). The AP-pinned structure minimizes the net magnetostatic coupling between the reference/pinned layers 206a, 206c and the CPP MR free ferromagnetic layer 210. The AP-pinned structure, also called a “laminated” pinned layer, is sometimes called a synthetic antiferromagnet (SAF). Seed layer 202 is provided to aid the proper growth of the antiferromagnetic layer 204 on lower shield layer 102.

Coupling layer 206b is typically Ru, Ir, Rh, Cr or alloys thereof Layers 206a, 206b, as well as the free ferromagnetic layer 210, are typically formed of crystalline CoFe or NiFe alloys, amorphous or crystalline CoFeB alloys, or a multi-layer structure of these materials, such as a CoFe/NiFe bilayer. Antiferromagnetic layer 204 is typically a Mn alloy, e.g., PtMn, NiMn, FeMn, IrMn, IrMnCr, PdMn, PtPdMn or RhMn.

A non-magnetic capping layer 212 is utilized between free layer 210 and the upper shield layer 104. The capping layer 212 provides corrosion protection and may be a single layer or multiple layers of different materials, such as Ru, Ta, Ti, or a Ru/Ta/Ru, Ru/Ti/Ru, or Cu/Ru/Ta trilayer.

In the presence of an external magnetic field in the range of interest, i.e., magnetic fields from recorded data on the disk media, the magnetization direction of free layer 210 will rotate while the magnetization direction of reference layer 206c will remain fixed and not rotate. The magnetic fields from the recorded data on the disk will cause rotation of the free-layer magnetization relative to the reference layer magnetization, which causes the resistance of the sensor stack to change. This change is detectable as a change in voltage drop across the sensor stack for a fixed sense current applied from top shield layer 104 perpendicularly through the sensor stack to bottom shield layer 102, or alternatively, a change in sense current for a fixed voltage drop across the sensor.

Insulating layer 106 is deposited on both sides of the sensor stack on sensor stack side edges 214a, 214b. Insulating layer 106 prevents short circuiting or shunting of the sensor sense current by the hard bias layers 112, 114 and seed layers 108, 110, which are composed of conductive metals. Insulating layer 106 is typically alumina (Al₂O₃) but may also be a silicon nitride (SiNₓ) or other metal oxide such as a Ta oxide, Ti oxide or Mg oxide. Preferably, insulating layer 106 may be thinner close to the sensor stack side edges 214 of the free layer to get the hard bias layers 112, 114 closer for higher effective field, but thicker on sections deposited on the lower shield layer 102 to obtain good insulating properties and avoid electrical shunting. A typical thickness range of insulating layer 106 is about 20 to 40 Å bordering the sensor stack edges adjacent the free layer, and about 30 to 50 Å on sections deposited on the lower shield layer 102.

Seed layers 108, 110 are deposited on insulating layer 106 to promote proper growth of hard bias layer 112. The seed layers provide a compatible interface between the insulating oxide and the metallic hard bias layer, as well as tailor the magnetic properties of the hard bias layer. In the present invention, layer 108 is composed of tantalum (Ta) and layer 110 is composed of tungsten (W). This specific combination results in an optimized magnetic properties for the chosen combination of hard bias layers 112 and 114. While combinations such as Ta and Cr or Ta and Cr/Ti have been reported in the prior art, these materials result in a lower coercivity H_{c} of the hard bias layers. As the data density increases in magnetic recording disk drives, there is a requirement for a decrease in the read head dimensions, including the upper shield to lower shield (102-104) spacing. This reduction in spacing can only be achieved by reducing the film thickness of both the sensor stack and the hard bias layer stack (layers 106-116). It is an object of the present invention to provide reduced layer thickness of layers 108-114 while providing improved magnetic properties such as high H_{c}, high squareness S, and high remanence-thickness product (Mᵣt). The present invention obtains the required magnetic properties with reduced film thickness by the appropriate choice of seed layers combined with a dual composition hard bias layer 112, 114. First layer 112 is comprised of hard magnetic material having a relatively higher anisotropy than second layer 114. Second layer 114 is a soft magnetic layer having a higher relative magnetization than the first layer 112. First layer 112 is preferably composed of an alloy of Co and Pt. This alloy is preferably composed of 15-25 atomic % Pt, remainder Co, more preferably 18% Pt, remainder Co. Up to 8 atomic % Cr may be added to the Co—Pt alloy to improve corrosion resistance, however at the expense of reduced magnetization. Hereinafter, the abbreviated designation for this alloy will be CoPt₁₈, but it is understood the aforementioned limitations on the composition apply.

The second layer 114 is preferably composed of an alloy of Co and Fe having an Fe concentration between 45 and 75 atomic %. Preferably, an Fe concentration of 50% is utilized. Up to 4 atomic % Ni may be added to improve corrosion resistance, however at the expense of reduced magnetization. Hereinafter, the abbreviated designation for this alloy will be CoFe or CoFe₅₀, but it is understood the aforementioned limitations on the composition apply.

Capping layer 116 may be composed of Ta, Cr, a Ta/Cr bilayer or other appropriate materials.

The high anisotropy CoPt₁₈/high moment CoFe₅₀ bilayer provides a higher Mᵣ*t in the upper portion of the hard-bias at overall reduced thickness compared to a single CoPt₁₈ layer, thus effectively providing higher flux and stabilization to the free layer while reducing total hard-bias thickness and shield to shield spacing.

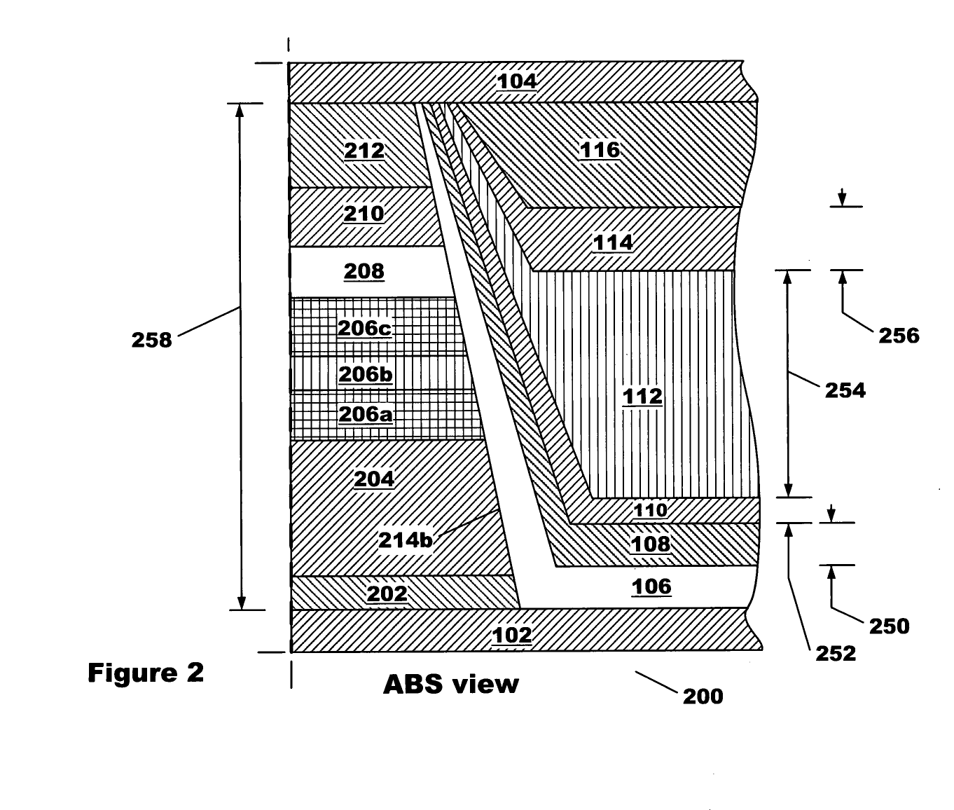

FIG. 2 is a second partial cross section view 200 of the CPP-MR sensor of FIG. 1, in accordance with an embodiment of the present invention. FIG. 2 is a bi-section of the sensor shown in FIG. 1, arranged to clarify film thickness dimensions. In one example embodiment of the present invention, first seed layer 108 is composed of Ta having a thickness dimension 250 of approximately 25 angstroms. Second seed layer 110 is composed of W having a thickness dimension 252 of approximately 25 angstroms. First hard bias layer 112 is composed of CoPt₁₈ having a thickness dimension 254 of approximately 124 angstroms.

Second hard bias layer 114 is composed of CoFe₅₀ having a thickness dimension 256 of approximately 23 angstroms. The aforementioned example has a capping layer 116 of approximately 70 angstroms, leading to shield to shield spacing 258 of approximately 310 angstroms. The example structure provides an H_{c} of 2100 Oe and a squareness S of 0.87.

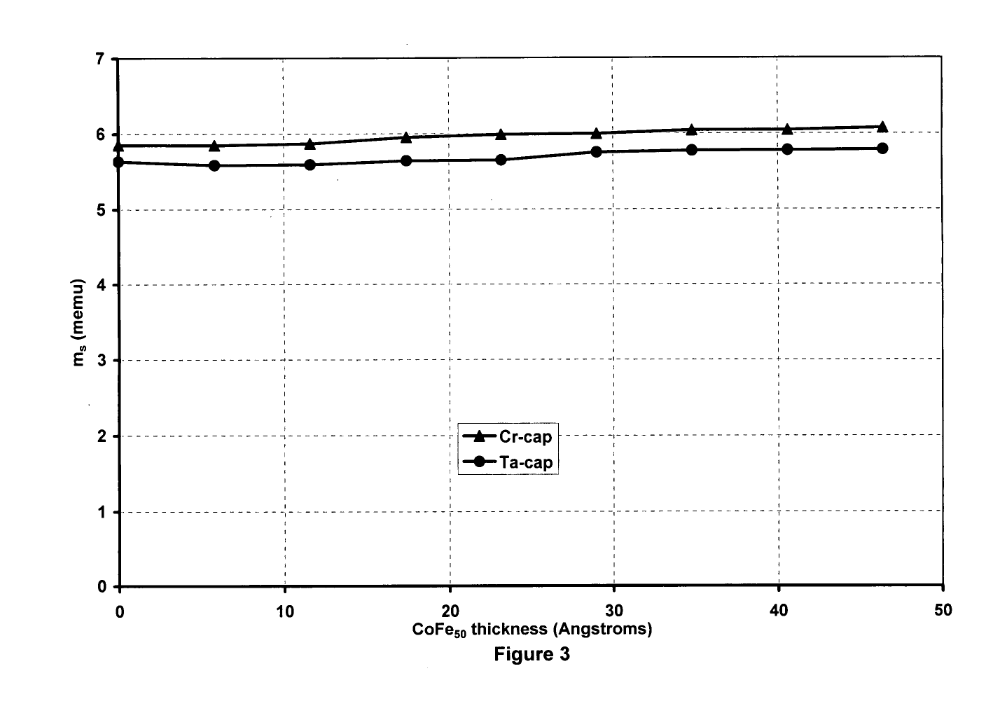

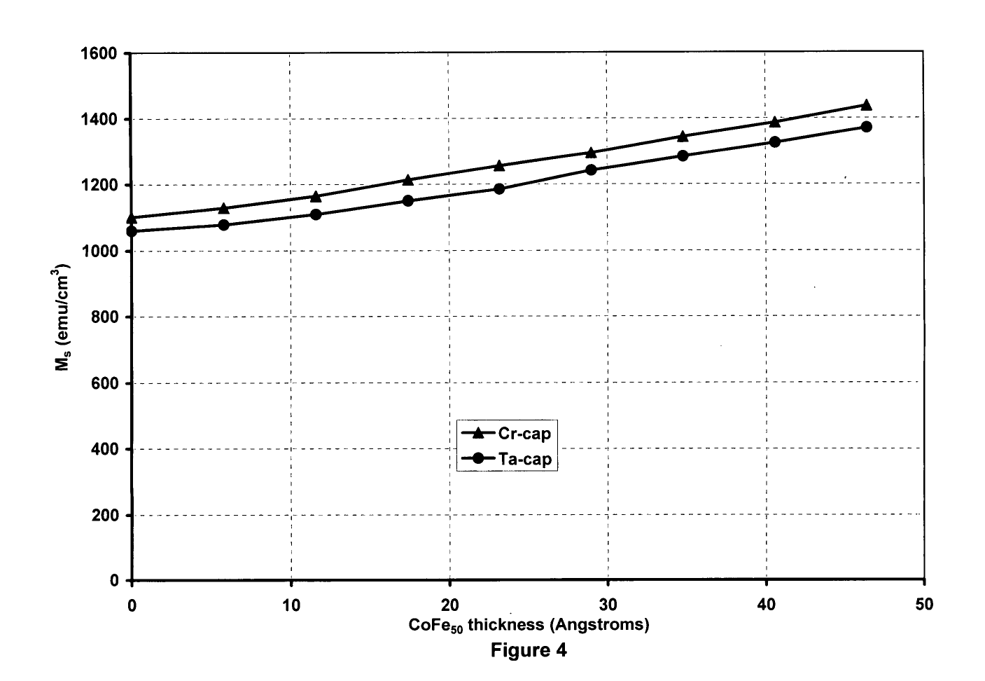

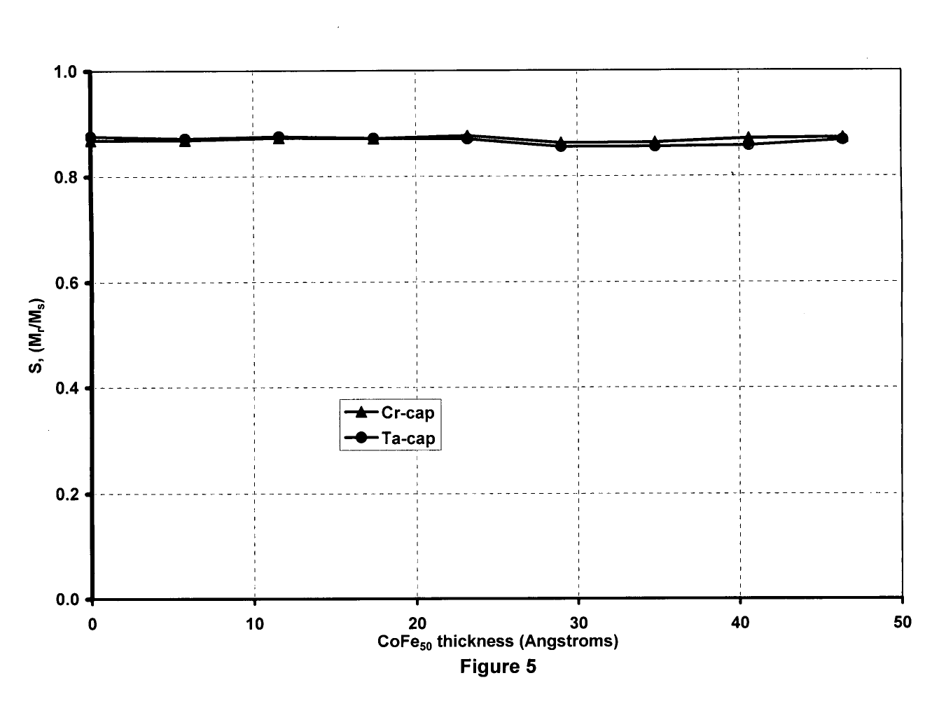

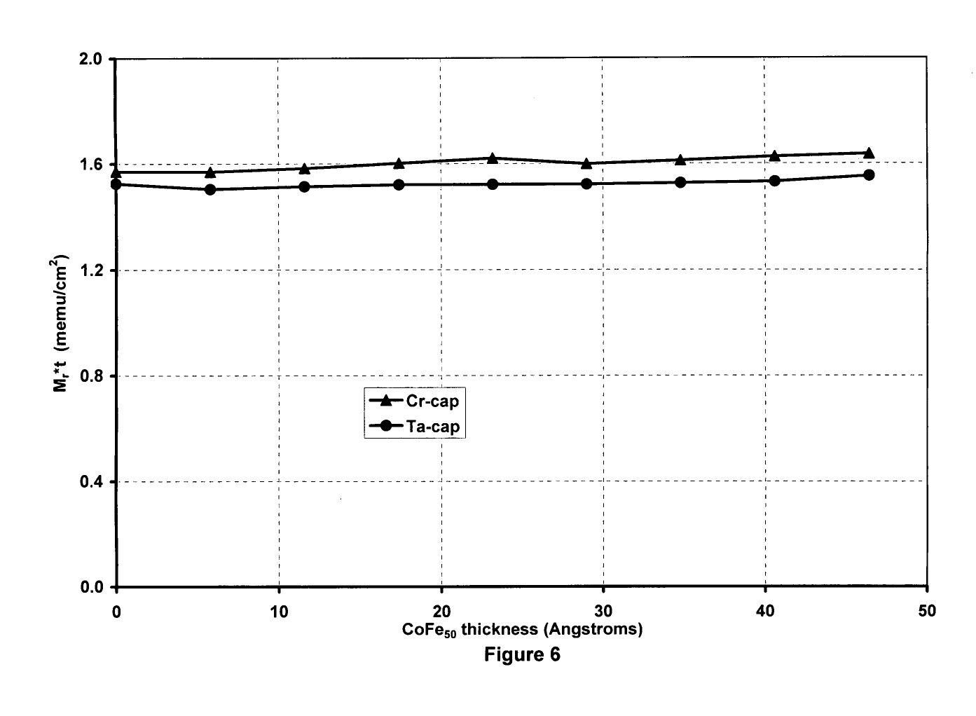

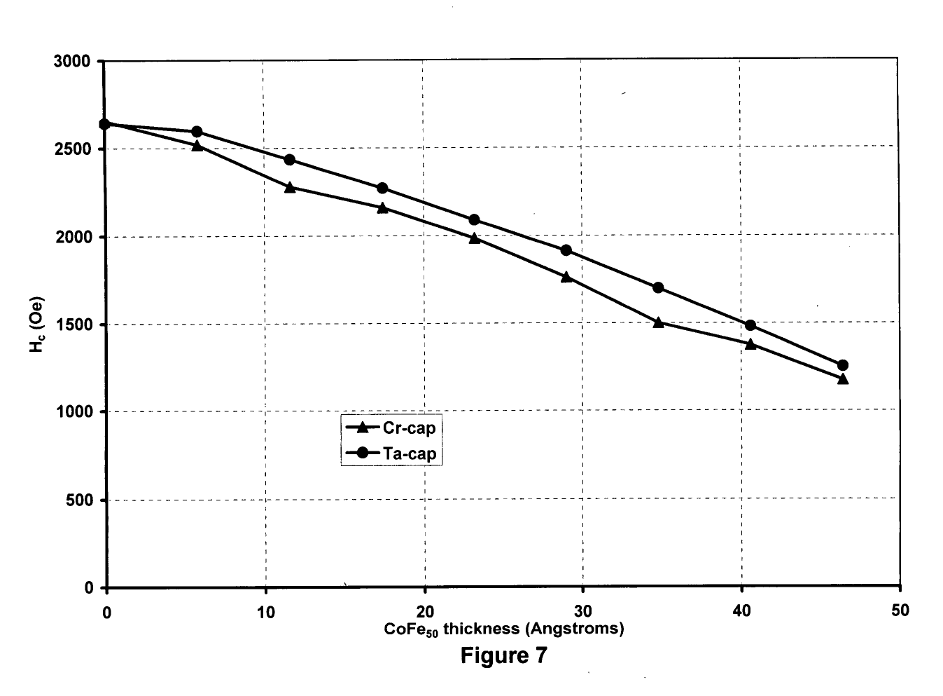

FIGS. 3-7 show graphs of various magnetic properties of hard-bias structures with a CoPt₁₈/CoFe₅₀ bilayer, where the thickness of the CoFe₅₀ layer 114 is varied in accordance with embodiments of the present invention. Data in these graphs was obtained for the condition of approximately constant total magnetic moment mₛ as described in more detail below. FIG. 3 is a graph of the total moment mₛ of the CoPt₁₈/CoFe₅₀ bilayer versus CoFe₅₀ layer thickness. FIG. 4 is a graph of saturation magnetization Mₛ of the CoPt₁₈/CoFe₅₀ bilayer versus CoFe₅₀ layer thickness. FIG. 5 is a graph of squareness S of the CoPt₁₈/CoFe₅₀ bilayer versus CoFe₅₀ layer thickness. FIG. 6 is a graph of Mᵣ*t of the CoPt₁₈/CoFe₅₀ bilayer versus CoFe₅₀ layer thickness. FIG. 7 is a graph of coercivity H_{c} of the CoPt₁₈/CoFe₅₀ bilayer versus CoFe₅₀ layer thickness.

For good thermal stability, a high coercivity is desirable. For a high magneto-static field to stabilize the free layer, a high remanent magnetization-thickness product Mᵣ*t is desirable. Since Mᵣ=Mₛ*S, a high squareness S and saturation magnetization Mₛ are needed. The present invention seeks to achieve this by optimizing the thickness of the two hard bias layers 112 and 114. Specifically, magnetic properties have been determined as a function of layer 114 (CoFe₅₀) thickness. In an example embodiment of the present invention, performance data is reported for a Ta/W seed (layers 108, 110) and CoPt₁₈/CoFe₅₀ (layers 112,114) hard-bias structure having Cr or Ta capping layers 116. However, as will be soon evident by evaluating the data of FIGS. 3-7, it is not possible to maximize both H_{c} and Mₛ by varying the CoFe₅₀ layer 114 thickness, as these variables show opposite trends. Since the magnetization of CoFe₅₀ (Mₛ˜1780 emu/cm³) is about 1.7 times higher than the magnetization of CoPt₁₈ (Mₛ˜1050 emu/cm³), a constant total moment mₛ is achieved by depositing a CoPt₁₈/CoFe₅₀ hard-bias bilayer, with a CoPt₁₈ layer thickness of approximately 164 Å-1.7*x, where x denotes the CoFe₅₀ thickness in A, from 0 Å to about 47 Å. The factor 1.7 is simply calculated from the magnetization ratio of CoFe₅₀ to CoPt₁₈. If the composition of CoPt alloy and CoFe alloy is changed within the preferred composition range described above to tune magnetic properties like coercivity and device dimensions, the ratio will have to be adjusted accordingly to achieve constant moment. It is noted here that the practical upper limit for CoFe₅₀ thickness is about 35 Å, for reasons to be explained below. FIG. 3 shows that the magnetic moment mₛ in a CoPt₁₈/CoFe₅₀ bilayer is approximately constant. FIG. 4 shows the overall magnetization Mₛ (that is mₛ/t, where t=164 Å-0.7*x is the thickness of the CoPt₁₈/CoFe₅₀ bilayer) increases linearly with CoFe₅₀ layer thickness, where
Mₛ=mₛ/t;
t=164Å-0.7*x=total CoPt₁₈/CoFe₅₀ bilayer thickness;
x=CoFe₅₀ layer thickness (dimension 256, FIG. 2)

FIG. 5 shows that within the same range the squareness S is approximately constant at about 0.86. Accordingly overall Mᵣ increases at the same rate as overall Mₛ. This is desirable because increasing overall Mᵣ with increasing CoFe₅₀ thickness x will decrease the total CoPt₁₈/CoFe₅₀ hard bias layer (layers 112 and 114) thickness t needed to stabilize the free layer, which in turn leads to a reduction in sensor stack height and reduced shield to shield dimensions. Since Mᵣ increases linearly with CoFe₅₀ thickness x, the total CoPt₁₈/CoFe₅₀ hard-bias bilayer thickness t needed to stabilize the free layer will decrease inversely proportional with CoFe₅₀ thickness x for constant Mᵣ*t, as is shown in FIG. 6. It should also be mentioned that within the composition range described the CoPt₁₈ and CoFe₅₀ layers are magnetically strongly coupled in the thickness regime investigated as has been established by measuring remanant magnetization curves, thus the approach of calculating overall Mₛ and Mᵣ by averaging is justified.

Turning to FIG. 7, it is also evident that increasing the CoFe₅₀ thickness reduces the H_{c} value. From a design standpoint, H_{c} values below approximately 1600 Oe are undesirable which imposes an upper limit on CoFe₅₀ layer thickness of about 35 Å. The lower limit of CoFe₅₀ layer thickness (without going to the commonly used condition of pure CoPt₁₈, i.e. zero CoFe₅₀) is approximately 5 Å, which is determined by the limits of current deposition technology. The arrow in FIG. 7 identifies an optimum CoFe₅₀ layer thickness of 23 Å and a value of of approximately 2000 Oe. Additionaly, thermal decay experiments performed on the described embodiments of the present invention show that thermal stability is as good as for a Ta/W seed CoPt₁₈ hard-bias structure with same moment.

The present invention is not limited by the previous embodiments heretofore described. Rather, the scope of the present invention is to be defined by these descriptions taken together with the attached claims and their equivalents.

What is claimed is:

1. A thin film magnetic head having a current perpendicular to plane magnetoresistive sensor comprising:
a first shield layer;
a sensor stack of layers deposited On an upper surface of said first shield layer, said sensor stack having a width at an air bearing surface defined by first and second side edges;
an insulating layer deposited on said first and second side edges of said sensor stack, and a portion of said upper surface of said first shield layer;
a first seed layer deposited on said insulating layer, said first seed layer comprising Ta;
a second seed layer deposited on said first seed layer, said second seed layer comprising W;
a first hard bias layer deposited on said second seed layer, said first hard bias layer comprising alloys of Co and Pt;
a second hard bias layer deposited on said first hard bias layer, said second hard bias layer comprising alloys of Co and Fe;
a capping layer deposited on said second hard bias layer; and
a second shield layer deposited on said capping layer, said sensor stack disposed between said first and second shield layers.

2. The thin film magnetic head as recited in claim 1, wherein said current perpendicular to plane magnetoresistive sensor is a tunneling magnetoresitive (TMR) sensor.

3. The thin film magnetic head as recited in claim 1, wherein said current perpendicular to plane magnetoresistive sensor is a giant magnetoresitive (GMR) sensor.

4. The thin film magnetic head as recited in claim 1, wherein said first hard bias layer comprises an alloy having a Pt concentration between 15 and 25 atomic %.

5. The thin film magnetic head as recited in claim 4, wherein said first hard bias layer comprises an alloy having a Pt concentration of approximately 18 atomic %.

6. The thin film magnetic head as recited in claim 4, wherein said first hard bias layer comprises an alloy having between 0 and 8 atomic % Cr.

7. The thin film magnetic head as recited in claim 1, wherein said second hard bias layer comprises an alloy having an Fe concentration between 45 and 75 atomic %.

8. The thin film magnetic head as recited in claim 7, wherein said second hard bias layer comprises an alloy having an Fe concentration of approximately 50 atomic %.

9. The thin film magnetic head as recited in claim 7, wherein said second hard bias layer comprises an alloy having between 0 and 4 atomic % Ni.

10. The thin film magnetic head as recited in claim 1, wherein said second hard bias layer has a thickness less than 35 angstroms.

11. The thin film magnetic head as recited in claim 10, wherein said second hard bias layer has a thickness greater than 5 angstroms.

12. The thin film magnetic head as recited in claim 11, wherein said second hard bias layer has a thickness of approximately 23 angstroms.

13. The thin film magnetic head as recited in claim 1, wherein said first and second hard bias layers have a coercivity greater than 2000 Oe.

14. The thin film magnetic head as recited in claim 1, wherein said first and second hard bias layers have a squareness ratio S greater than 0.8.

15. The thin film magnetic head as recited in claim 1, wherein said first and second hard bias layers have a combined thickness less than 150 angstroms.

16. A thin film magnetic head having a current perpendicular to plane magnetoresistive sensor comprising:
a first shield layer;
a sensor stack of layers deposited on an upper surface of said first shield layer, said sensor stack having a width at an air bearing surface defined by first and second side edges;
an insulating layer deposited on said first and second side edges of said sensor stack, and a portion of said upper surface of said first shield layer;
a first seed layer deposited on said insulating layer, said first seed layer comprising Ta;
a second seed layer deposited on said first seed layer, said second seed layer comprising W;
a first hard bias layer deposited on said second seed layer, said first hard bias layer comprising alloys of Co and Pt;
a second hard bias layer deposited on said first hard bias layer, said second hard bias layer comprising alloys of Co and Fe, said first and second hard bias layers having a combined thickness less than 150 angstroms and a coercivity H_{c} greater than 2000 Oe;
a capping layer deposited on said second hard bias layer; and
a second shield layer deposited on said capping layer, said sensor stack disposed between said first and second shield layers.

17. The thin film magnetic head as recited in claim 16, wherein said current perpendicular to plane magnetoresistive sensor is a tunneling magnetoresitive (TMR) sensor.

18. The thin film magnetic head as recited in claim 16, wherein said current perpendicular to plane magnetoresistive sensor is a giant magnetoresitive (GMR) sensor.

19. The thin film magnetic head as recited in claim 16, wherein said first hard bias layer comprises an alloy having a Pt concentration between 15 and 25 atomic %.

20. The thin film magnetic head as recited in claim 19, wherein said first hard bias layer comprises an alloy having a Pt concentration of approximately 18 atomic %.

21. The thin film magnetic head as recited in claim 19, wherein said first hard bias layer comprises an alloy having between 0 and 8 atomic % Cr.

22. The thin film magnetic head as recited in claim 16, wherein said second hard bias layer comprises an alloy having an Fe concentration between 45 and 75 atomic %.

23. The thin film magnetic head as recited in claim 22, wherein said second hard bias layer comprises an alloy having an Fe concentration of approximately 50 atomic %.

24. The thin film magnetic head as recited in claim 22, wherein said second hard bias layer comprises an alloy having between 0 and 4 atomic % Ni.

25. The thin film magnetic head as recited in claim 16, wherein said second hard bias layer has a thickness less than 35 angstroms.

26. The thin film magnetic head as recited in claim 25, wherein said second hard bias layer has a thickness greater than 5 angstroms.

27. The thin film magnetic head as recited in claim 16, wherein said second hard bias layer has a thickness of approximately 23 angstroms.
